(19) United States
(12) Patent Application Publication
(10) Pub. No.: US 2014/0151681 A1
(43) Pub. Date: Jun. 5, 2014

(54) ORGANIC ELECTROLUMINESCENCE DEVICE

(71) Applicant: Masataka Iwasaki, Ehime (JP)

(72) Inventor: Masataka Iwasaki, Ehime (JP)

(21) Appl. No.: 14/236,367

(22) PCT Filed: Aug. 2, 2012
(86) PCT No.: PCT/JP2012/069654

§ 371 Date: Jan. 31, 2014

(30) Foreign Application Priority Data
Aug. 3, 2011 (JP) 2011-169694

(51) Int. Cl. H01L 51/50

(52) U.S. Cl. CPC H01L 51/5068; H01L 51/5064
USPC 257/40

(57) ABSTRACT

In order to provide an organic electroluminescent element which has excellent luminous efficiency and long service life, this organic electroluminescent element is provided with: a positive electrode; a negative electrode; an organic light emitting layer that is arranged between the positive electrode and the negative electrode; a first layer that is formed of sodium fluoride and arranged between the negative electrode and the organic light emitting layer so as to be in contact with the organic light emitting layer; and a second layer that is arranged between the first layer and the negative electrode and contains a first material and a second material, said first material being composed of an organic material and containing electrons donated from the second material.

### TECHNICAL FIELD

The present invention relates to an organic electroluminescence device.

### BACKGROUND ART

An attention is now paid toward an organic EL display using an organic electroluminescence device. The organic electroluminescence device used in the organic EL display includes an anode, a cathode, and a light emitting layer disposed between the anode and the cathode, and holes and electrons injected respectively from the anode and the cathode are recombined in the light emitting layer to thereby emit light.

For the purpose of improving device characteristics such as luminance efficiency, the organic electroluminescence device may be sometimes provided with a layer, which accelerates injection of electrons from the cathode and transfer of electrons to the light emitting layer, on the cathode side between the anode and the cathode. This layer accelerating electron transfer is called an electron injecting layer or an electron conducting layer and, for example, Patent Document 1 proposes an organic electroluminescence device in which an electron injecting layer containing an alkali metal or an alkali earth metal as a main component is provided in contact with a transparent electrode on the cathode side, and also a cathode buffer layer is formed between the electron injecting layer and a light emitting layer in contact with the electron injecting layer. Patent Document 1 discloses that this cathode buffer layer protects the electron injecting layer and the organic light emitting layer when a cathode film is formed, and also prevents oxidation of an alkali metal or an alkali earth metal, thus enabling stable feed of electrons to the organic light emitting layer, leading to suppression of deterioration with time.

Patent Document 2 also proposes an organic electroluminescence device including, on a substrate serving as a support, a substrate electrode, a hole injecting/conducting layer, a controlling layer on a hole side, a light emitting layer, an electron controlling layer, an electron injecting/conducting layer, and an anode coated electrode laminated thereon. It is considered that the controlling layer suppressed the generation of non-radiative recombination to thereby prevent deterioration of luminance efficiency in this organic electroluminescence device.

In the organic electroluminescence device of Patent Document 2, the controlling layer is formed of an organic substance, and press-retains a large number of charged particles (holes on the hole side, electrons on the electron side) on a boundary of a charged particle C₁-1NJ conducting layer/controlling layer based on a relation of energy level with an adjacent layer while efficiently press-retains a small number of charged particles on a boundary of a light emitting layer/controlling layer.

### PRIOR ART DOCUMENTS

### Patent Document

Patent Document 1: WO 2009/130858 A
Patent Document 2: JP 2004-514257 W

### SUMMARY OF INVENTION

### Problems to be Solved by the Invention

However, it is required for an organic electroluminescence device to have a longer lifetime while maintaining excellent luminance efficiency.

Thus, an object of the present invention is to provide an organic electroluminescence device which has excellent luminance efficiency and also has a long lifetime.

### Means for Solving the Problems

As a result of intensive study so as to achieve the above object, it has been found that the lifetime can be prolonged without causing deterioration of luminance efficiency by providing a layer made of sodium fluoride between a cathode and an organic light emitting layer in contact with the organic light emitting layer, thus completing the present invention.

Namely, an organic electroluminescence device according to the present invention includes:

an anode;

a cathode;

an organic light emitting layer provided between the anode and the cathode;

a first layer made of sodium fluoride provided between the cathode and the organic light emitting layer in contact with the organic light emitting layer; and
a second layer located between the first layer and the cathode, including a first material composed of an organic substance, and a second material, the material of the second material being a material capable of donating electrons to the first material.

In an aspect of the present invention, a film thickness of the first layer is in a range from 0.1 to 10 nm.

In an aspect of the present invention, a weight ratio of the first material to the second material is in a range from 1,000:1 to 5:1 in the second layer.

In an aspect of the present invention, the cathode is made of metal.

In an aspect of the present invention, the cathode is made of Al.

In an aspect of the present invention, a third layer is further included between the cathode and the second layer, and the third layer is made of metal.

In an aspect of the present invention, the third layer is made of Al.

In an aspect of the present invention, the first material is composed of an electron transporting organic substance.

In an aspect of the present invention, the material of the second material is metal.

In an aspect of the present invention, the second layer is in contact with the first layer, and the cathode or the third layer is in contact with the second layer.

### Advantageous Effects of Invention

The organic electroluminescence device according to the present invention configured as mentioned above has excellent luminance efficiency and also has long lifetime since it includes a first layer made of the sodium fluoride provided in contact with an organic light emitting layer.

### BRIEF DESCRIPTION OF THE DRAWINGS

FIG. 1 is a schematic cross-sectional view schematically illustrating the structure of an organic electroluminescence device of the embodiment according to the present invention.

### BEST MODE FOR CARRYING OUT THE INVENTION

An organic electroluminescence device of the embodiment according to the present invention will be described below with reference to the accompanying drawings.

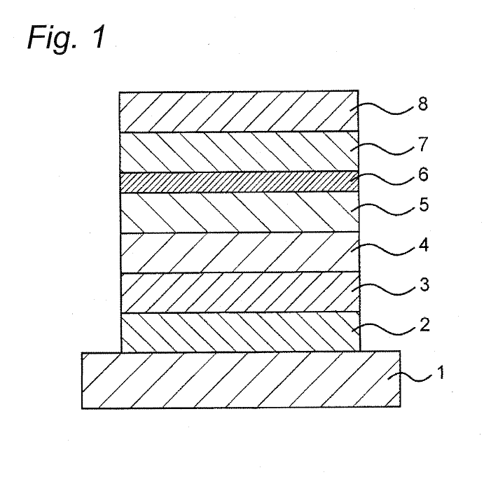

As illustrated in FIG. 1, the organic electroluminescence device of the present embodiment is configured by laminating, on a substrate 1, an anode 2, for example, made of an ITO transparent electrode; a hole injecting layer 3, for example, made of tungsten oxide (WOx); a hole transporting layer 4, for example, made of a hole transporting organic compound; an organic light emitting layer 5 in which holes and electrons to be injected are recombined to form excitons, thus emitting light; a sodium fluoride layer 6; an electron injecting layer 7 including, for example, an electron transporting organic substance and an electron donating metal; and a cathode 8, for example, made of Al.

The organic electroluminescence device of the present embodiment is configured so as to take out light from the substrate side, but the present invention is not limited thereto.

In the organic electroluminescence device of the present embodiment,

the substrate 1 serves to support a device laminated structure and, in the present embodiment, a transparent substrate is used so as to emit light through the substrate.

The anode 2 is an electrode to be connected with a drive circuit and is, for example, a transparent electrode composed of an ITO transparent electrode. The material of the anode 2 is selected from materials which are easy to connect with the drive circuit, and also can reduce an energy barrier between the anode and a hole injecting layer 3.

The hole injecting layer 3 is a layer which reduces an energy barrier of hole injection at the interface between the hole injecting layer and the anode to thereby facilitate hole injection. The material of the hole injecting layer 3 to be used is, for example, an inorganic compound such as tungsten oxide, or a hole transporting organic compound doped with an electron donating material.

The hole transporting layer 4 is a layer which enables transfer of holes to an organic light emitting layer 5 and is, for example, made of a hole transporting organic compound. It is also possible to impart a function of blocking electrons, which try to transfer from the organic light emitting layer 5 to hole transporting layer 4, to the hole transporting layer 4.

The organic light emitting layer 5 is a layer in which holes and electrons to be injected are recombined to form excitons, thus emitting light.

The sodium fluoride layer 6 is a first layer and is, for example, a layer which adjusts or controls the amount of electrons to be injected to the organic light emitting layer 5 by adjusting the thickness thereof.

The electron injecting layer 7 is a second layer and is a layer which reduces an energy barrier of electron injection at the interface between the electron injecting layer and the cathode to thereby facilitate electron injection. The electron injecting layer 7 is, for example, made of an electron transporting organic compound doped with an electron donating material (dopant). The electron transporting organic compound can accept electrons from the electron donating material and reduce an energy barrier between the electron injecting layer and the cathode.

The cathode 8 is an electrode to be connected with a drive circuit and the material is, for example, selected from materials which are easy to connect with the drive circuit, and also can reduce an energy barrier between the cathode and an electron injecting layer 7.

In the organic electroluminescence device of the present embodiment, it is important that the sodium fluoride layer 6 is provided between the cathode 8 and the organic light emitting layer 5 (on the cathode side) in contact with the organic light emitting layer 5. As mentioned above, the adjustment or control of the amount of electrons to injected, or exertion of a function corresponding to the attribute of electrons, in addition to the adjustment or control of the amount of electrons to be injected, enables prolonging of the lifetime without causing deterioration of luminance efficiency.

Namely, sodium fluoride has low conductivity and is therefore suited to adjust or control the amount of electrons to be injected from the cathode. Furthermore, sodium fluoride has chemically comparatively stable properties and therefore can continuously adjust or control the amount of electrons to be injected over a long period. Of alkali metal fluorides, sodium fluoride having a large work function of alkali metal is more preferred from the viewpoint of the effect of adjusting or controlling the amount of electrons to be injected.

The organic electroluminescence device of the embodiment will be described in detail below.

### <Substrate 1>

The material of the substrate, which constitutes the organic electroluminescence device of the present invention, may be a material which forms an electrode and does not cause a chemical change in the case of forming an organic substance and, for example, glasses, plastics, polymeric films, metal films, silicone substrates, and laminates thereof can be used. The substrate is commercially available, or can be produced by a known method.

### <Anode 2>

In the anode which constitutes the organic electroluminescence device of the present invention, a work function of a surface of the light emitting layer side is preferably 4.0 eV or more, from the viewpoint of feedability of holes to an organic semiconductor material used in a hole injecting layer, a hole transporting layer, a light emitting layer, and the like.

It is possible to use, as the material of the anode, metals, alloys, electrically conductive compounds such as metal oxides and metal sulfides, or mixtures thereof. Specific examples thereof include conductive metal oxides such as tin oxide, zinc oxide, indium oxide, indium tin oxide (ITO), indium zinc oxide (IZO), and molybdenum oxide; metals such as gold, silver, chromium, and nickel; and mixtures of these conductive metal oxides and metals.

The anode may have a single layer structure composed of one, or two or more kinds of these materials, or a multilayer structure composed of a plurality of layers each having the same or different composition. In the case of the multilayer structure, it is more preferred to use a material having a work function of 4.0 eV or more in an outermost layer of the light emitting layer side.

There is no particular limitation on the method for the production of an anode, and a known method can be used and examples thereof include a vacuum deposition method, a sputtering method, an ion plating method, a plating method, and the like.

The film thickness of the anode is usually from 10 nm to 10 μm, and preferably from 50 nm to 500 nm.

Furthermore, the anode may be sometimes subjected to a surface treatment with UV ozone, a silane coupling agent, or a solution containing an electron accepting compound such as 2,3,5,6-tetrafluoro-7,7,8,8-tetracyanoquinodimethane after producing by the above-mentioned method. Electrical connection with an organic layer in contact with the anode is improved by the surface treatment.

### <Hole Injecting Layer 3>

In the organic electroluminescence device of the present invention, it is possible to use, as the material which forms a hole injecting layer 3, conductive metal oxides such as vanadium oxide, tantalum oxide, tungsten oxide, molybdenum oxide, ruthenium oxide, and aluminum oxide.

The hole injecting layer 3 can also be formed of a material in which a hole transporting organic compound used in the below-mentioned hole transporting layer 4 is doped with an electron accepting material (dopant). In the hole transporting organic compound layer doped with an electron accepting material, the hole transporting organic compound exists in a state where electrons are taken by the electron accepting material, thus enabling a reduction in energy barrier between the anode and a hole injecting layer.

Examples of the electron accepting material (dopant) include a quinone compound, a transition metal complex compound, an organic closed-shell anion compound, a fluorene compound having a cyano group and a nitro group, tetracyanoethylene, tetracyanobutadiene, lithium hexafluoroarsenate, phosphoric acid trichloride, fluoranyl, chloranyl, bromanyl, and the like. The quinone compound includes, for example, a p-benzoquinone derivative, a tetracyanoquinodimethane derivative, a 1,4-napthoquinone derivative, and a diphenoquinone derivative. Examples of the p-benzoquinone derivative include 2,3-dichloro-5,6-dicyano-p-benzoquinone (DDQ), 2,3-dibromo-5,6-dicyano-p-benzoquinone (DBDQ), 2,3-diiodo-5,6-dicyano-p-benzoquinone (DIDQ), and 2,3-dicyano-p-benzoquinone (Q(CN)₂). Examples of the tetracyanoquinodimethane derivative include 2,3,5,6-tetrafluoro-7,7,8,8-tetracyanoquinodimethane (F4-TCNQ), 2,3,5-trifluoromethyl-7,7,8,8-tetracyanoquinodimethane (CF3-TCNQ), 2,5-difluoro-7,7,8,8-tetracyanoquinodimethane (F2-TCNQ), 2-monofluoro-7,7,8,8-tetracyanoquinodimethane (F-TCNQ), 11,11,12,12-tetracyanonaptho-2,6-quinodimethane (TNAP), 7,7,8,8-tetracyanoquinodimethane (TCNQ), and decyl-7,7,8,8-tetracyanoquinodimethane (C10-TCNQ). Examples of the 1,4-napthoquinone derivative include 2,3-dicyano-5-nitro-1,4-napthoquinone (DCNNQ), and 2,3-dicyano-1,4-napthoquinone (DCNQ). Examples of the diphenoquinone derivative include 3,3′,5,5′-tetrabromo-diphenoquinone (TBDQ). The transition metal complex compound includes, for example, (TPP)₂Pd(dto)₂, (TPP)₂Pt(dto)₂, (TPP)₂Ni(dto)₂, (TPP)₂Cu(dto)₂, and (TBA)₂Cu(ox)₂, in which TPP represents triphenylphosophine, TBA represents tetrabutylammonium, dto represents dithiooxalato, and ox represents oxalato. The organic closed-shell anion compound includes, for example, picrate and The fluorene compound having a cyano group and a nitro group includes, for example, 9-dicyanomethylene-2,4,5,7-tetranitro-fluorenone (DTENF), 9-dicyanomethylene-2,4,7-trinitro-fluorenone (DTNF), 2,4,5,7-tetranitrofluorenone (TENF), and 2,4,7-trinitrofluorenone (TNF).

The material may be a single component, or a composition composed of a plurality of components. The hole injecting layer may have a single layer structure composed of one, or two or more kinds of the above materials, or a multilayer structure composed of a plurality of layers each having the same or different composition.

There is no particular limitation on the method for the formation of an injecting layer 3, and a known method can be used. Examples of the method for the formation of an injecting layer 3 include a vacuum deposition method, a sputtering method, and an ion plating method in the case of an inorganic compound material, and examples thereof include a vacuum deposition method, a transfer method such as laser transfer method or a heat transfer method, a method due to film formation from a solution (a solution mixed with a polymeric binder may be used) in the case of a low molecular organic material. Examples thereof include a method due to film formation from a solution in the case of a polymeric organic material.

When the hole injection material is a low molecular compound such as a pyrazoline derivative, an arylamine derivative, a stilbene derivative, or a triphenyldiamine derivative, it is possible to form a hole injecting layer using a vacuum deposition method.

Examples of the method for film formation from a solution include coating methods and printing methods, such as a spin coating method, a casting method, a bar coating method, a slit coating method, a spray coating method, a nozzle coating method, a gravure printing method, a screen printing method, a flexo printing method, and an ink-jet printing method. Examples of the solvent used in the film formation from a solution include alcohols such as water, methanol, ethanol, and isopropyl alcohol; ketones such as acetone and methyl ethyl ketone; organic chlorine compounds such as chloroform and 1,2-dichloroethane; aromatic hydrocarbons such as benzene, toluene, and xylene; aliphatic hydrocarbons such as normal hexane and cyclohexane; compounds having an amide bond, such as dimethylformamide; and sulfoxides such as dimethyl sulfoxide. These solvents may be used alone, or two or more kinds of them may be used in combination.

### <Hole Transporting Layer 4>

In the organic electroluminescence device of the present invention, the hole transporting organic compound material which forms a hole transporting layer 4 includes, for example, a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidyne-based compound, a porphyrin-based compound, a polysilane-based compound, a poly(N-vinylcarbazole) derivative, an organic silane derivative, and polymeric compounds including these structures. It is also possible to exemplify conductive polymers and oligomers, such as an aniline-based copolymer, a thiophene oligomer, and polythiophene; and organic conductive materials such as polypyrrole.

The material may be a single component, or a composition composed of a plurality of components. The hole transporting layer 4 may have a single layer structure composed of one, or two or more kinds of these materials, or a multilayer structure composed of a plurality of layers each having the same or different composition.

There is no particular limitation on the film formation method of the hole transporting layer 4, and examples thereof include the method similar to the film formation method of the hole injecting layer.

Examples of the method for film formation from a solution include the above-mentioned coating methods and printing methods, such as a spin coating method, a casting method, a bar coating method, a slit coating method, a spray coating method, a nozzle coating method, a gravure printing method, a screen printing method, a flexo printing method, and an ink-jet printing method. In the case of using a sublimable compound material, a vacuum deposition method, a transfer method, and the like can be exemplified.

Examples of the solvent used in film formation from a solution include solvents listed in the film formation method of the hole injecting layer.

### <Organic Light Emitting Layer 5>

In the organic electroluminescence device of the present invention, a light emitting layer is preferably formed from a polymeric light emitting material. It is possible to suitably use, as the polymeric light emitting material, conjugated polymeric compounds such as a polyfluorene derivative, a polyparaphenylenevinylene derivative, a polyphenylene derivative, a polyparaphenylene derivative, a polythiophene derivative, polydialkylfluorene, polyfluorenebenzothiadiazole, and polyalkylthiophene.

The light emitting layer may contain polymer-based pigment compounds such as perylene-based pigments, coumarin-based pigments, and rhodamine-based pigment; and low molecular pigment compounds such as rubrene, perylene, 9,10-diphenylanthracene, tetraphenylbutadiene, nile red, coumarin 6, and quinacridone. The light emitting layer may also contain a naphthalene derivative, anthracene or derivatives thereof, perylene or derivatives thereof, polymethine-based, xanthene-based, coumarin-based, or cyanine-based pigments, a metal complex of 8-hydroxyquinoline or derivatives thereof, aromatic amine, tetraphenylcyclopentadiene or derivatives thereof, or tetraphenylbutadiene or derivatives thereof, a metal complex emitting phosphorescence such as tris(2-phenylpyridine)iridium, and the like.

The light emitting layer possessed by the organic electroluminescence device of the present invention may be made of a mixture of a non-conjugated polymeric compound [for example, polyvinylcarbazole, polyvinyl chloride, polycarbonate, polystyrene, polymethyl methacrylate, polybutyl methacrylate, polyester, polysulfone, polyphenylene oxide, polybutadiene, poly(N-vinylcarbazole), a hydrocarbon resin, a ketone resin, a phenoxy resin, polyamide, ethyl cellulose, vinyl acetate, an ABS resin, polyurethane, a melamine resin, an unsaturated polyester resin, an alkyd resin, an epoxy resin, a silicone resin, a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidyne-based compound, a porphyrin-based compound, a polysilane-based compound, a poly(N-vinylcarbazole) derivative, a polymer containing an organic silane derivative] with the above-mentioned light emitting organic compound such as an organic pigment or a metal complex.

Specific examples of such polymeric compound include polyfluorene, derivatives and copolymers thereof, polyartylene, derivatives and copolymers thereof, polyarylenevinylene, derivatives and copolymers thereof, and an aromatic amine and (co)polymers of derivatives thereof disclosed in WO 97/09394, WO 98/27136, WO 99/54385, WO 00/22027, WO 01/19834, GB2340304A, GB2348316, U.S. Pat. No. 573,636, U.S. Pat. No. 5,741,921, U.S. Pat. No. 5,777,070, EP0707020, JP 9-111233 A, JP 10-324870 A, JP 2000-80167 A, JP 2001-123156 A, JP 2004-168999 A, JP 2007-162009, and “Development and Constituent Materials of Organic EL Device” (CMC Publishing Co., Ltd., 2006).

Specific examples of the low molecular compound include compounds disclosed in JP 57-51781A, Organic Thin-Film Work Function Data Sheet [2nd Edition] (CMC Publishing Co., Ltd., 2006), and “Development and Constituent Materials of Organic EL Device” (CMC Publishing Co., Ltd., 2006).

The material may be a single component, or a composition composed of a plurality of components. The light emitting layer may have a single layer structure composed of one, or two or more kinds of the above materials, or a multilayer structure composed of a plurality of layers each having the same or different composition.

There is no particular limitation on the film formation method of the light emitting layer, and examples thereof include the method similar to the film formation method of the hole injecting layer. Examples of the method for film formation from a solution include the above-mentioned coating methods and printing methods, such as a spin coating method, a casting method, a bar coating method, a slit coating method, a spray coating method, a nozzle coating method, a gravure printing method, a screen printing method, a flexo printing method, and an ink-jet printing method. In the case of using a sublimable compound material, a vacuum deposition method, a transfer method, and the like can be exemplified.

The optimum value of the film thickness of the light emitting layer varies depending on the material to be used, and the film thickness may be selected so that a driving voltage and luminance efficacy become a moderate value. There is a need to adjust to the thickness at which pinholes are not generated, and too large thickness is not preferred since a driving voltage of the device increases. Therefore, the film thickness of the light emitting layer is, for example, from 5 nm to 1 μm, preferably from 10 nm to 500 nm, and more preferably from 30 nm to 200 nm.

### <Sodium Fluoride Layer 6>

Sodium fluoride has low conductivity and is also chemically stable, and thus enabling continuous adjustment or control of the amount of electrons to be injected over a long period.

The film thickness of a sodium fluoride layer 6 is preferably 0.1 nm or more so as to effectively prolong the lifetime, and is also preferably 10 nm or less so as to control a driving voltage to a low value.

The film formation method for the sodium fluoride layer 6 includes vacuum deposition, application, transfer, and the like.

The sodium fluoride layer 6 is preferably formed in a film thickness in a range from 0.1 to 10 nm for the following reason. That is, if the film thickness of the sodium fluoride layer 6 is more than 10 nm, a driving voltage may gradually increases. If the film thickness is less than 0.1 nm, it may become difficult to adjust the amount of electrons to be injected.

### <Electron Injecting Layer 7>

As mentioned above, in the present invention, an electron injecting layer 7 is, for example, made of an electron transporting organic compound containing an electron donating material as a dopant so as to reduce an energy barrier of hole injection at the interface between a cathode and an electron injecting layer. At this time, the electron transporting organic compound is a first material and the electron donating material is a second material.

Examples of the electron transporting organic compound include a triazole derivative, an oxazole derivative, an oxadiazole derivative, an imidazole derivative, a fluorenone derivative, benzoquinone or derivatives thereof, napthoquinone or derivatives thereof, anthraquinone or derivatives thereof, tetracyanoanthraquinodimethane or derivatives thereof, a fluorenone derivative, diphenyldicyanoethylene or derivatives thereof, a diphenoquinone derivative, an anthraquinodimethane derivative, an anthrone derivative, a thiopyran dioxide derivative, a carbodiimide derivative, a fluorenylidene methane derivative, a distyrylpyrazine derivative, an aromatic tetracarboxylic anhydride such as naphthalene or perylene, a phthalocyanine derivative, various metal complexes such as a metal complex of a 8-quinolinol derivative, metal phthalocyanine, a metal complex containing benzoxazole or benzothiazole as a ligand, an organic silane derivative, a phenanthroline derivative such as 2,9-dimethyl-4,7-diphenyl-1,10-phenanthroline (bathocuproine), and the like.

Examples of the electron donating material (dopant) include metals such as Ba, Li, Na, K, Rb, Cs, Fr, Mg, Ca, Sr, Ra, and Be, salts of these metals, compounds containing these metals, alloys containing these metals, and the like. The electron donating material is preferably metal, and more preferably Ba, Li, Cs, Mg, or Ca. A difference between an absolute value of energy of a lowest unoccupied molecular orbital (LUMO) of an electron transporting organic compound and an absolute value of a work function of an electron donating material is preferably 1.0 eV or less.

In the present invention, a weight ratio of an electron transporting organic compound to an electron donating material (dopant) is preferably in a range from 1,000:1 to 5:1 for the following reason. That is, if the weight ratio of an electron donating material (dopant) to an electron transporting organic compound is more than 20%, a light transmittance may decrease due to coloration. If the weight ratio of an electron donating material (dopant) to an electron transporting organic compound is less than 0.1%, it may become difficult to obtain preferred electron transportability.

In the electron injecting layer 7, a weight ratio of an electron transporting organic compound to an electron donating material (dopant) is more preferably set in a range from 100:1 to 10:1. When the weight ratio is in this range, it is possible to easily obtain satisfactory electron transportability while ensuring preferred light transmittance.

The above-mentioned material may be a single component, or a composition composed of a plurality of components. The electron injecting layer may have a single layer structure composed of one, or two or more kinds of these materials, or a multilayer structure composed of a plurality of layers each having the same or different composition.

There is no particular limitation on the film formation method of the electron injecting layer 7, and examples thereof include the method similar to the film formation method of the hole injecting layer.

Examples of the method for film formation from a solution include the above-mentioned coating methods and printing methods, such as a spin coating method, a casting method, a bar coating method, a slit coating method, a spray coating method, a nozzle coating method, a gravure printing method, a screen printing method, a flexo printing method, and an ink-jet printing method. In the case of using a sublimable compound material, a vacuum deposition method, a transfer method, and the like can be exemplified.

Examples of the solvent used in film formation from a solution include solvents listed in the film formation method of the hole injecting layer.

The optimum value of the film thickness of the electron injecting layer 7 varies depending on the material to be used, and the film thickness may be selected so that a driving voltage and luminance efficacy become a moderate value. There is a need to adjust to the thickness at which pinholes are not generated, and too large thickness is not preferred since a driving voltage of the device increases. Therefore, the film thickness of electron injecting layer 7 is, for example, from 1 nm to 1 μm, preferably from 2 nm to 500 nm, and more preferably from 5 nm to 100 nm.

### <Cathode 8>

The material of the cathode possessed by the organic electroluminescence device of the present invention is preferably a material which has low work function and is easy to inject electrons into a light emitting layer, and also has high electric conductivity. In the organic electroluminescence device in which light is taken out from the anode side, the material of the cathode is preferably a material having a high visible light reflectance so as to reflect light from the light emitting layer toward the anode side by the cathode. The cathode 8 is preferably made of metal. While the cathode may be composed of a plurality of layers, it is preferred that at least the electron injecting layer 7 side is made of metal and the metal layer is in contact with the electron injecting layer 7. In this way, if the metal layer of the cathode 8 is in contact with the electron injecting layer 7, it is possible to satisfactory inject electrons into the electron injecting layer from the cathode.

It is possible to use, as the material of the cathode, for example, alkali metal, alkali earth metal, transition metal and group III-B metal, and the like. It is possible to use, as the material of the cathode, for example, metals such as lithium, sodium, potassium, rubidium, cesium, beryllium, magnesium, calcium, strontium, barium, aluminum, scandium, vanadium, zinc, yttrium, indium, cerium, samarium, europium, terbium, and ytterbium; alloys of two or more kinds of the above-mentioned metals; alloys of one or more kinds of the above-mentioned metals with one or more kinds of gold, silver, platinum, copper, manganese, titanium, cobalt, nickel, tungsten, and tin; or graphite or a graphite intercalation compound. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, a calcium-aluminum alloy, and the like. It is possible to use, as the cathode, transparent conductive electrodes made of a conductive metal oxide, a conductive organic substance, and the like. Specific examples of the conductive metal oxide include indium oxide, zinc oxide, tin oxide, ITO, and IZO, and examples of the conductive organic substance include polyaniline or derivatives thereof, polythiophene or derivatives thereof, and the like. The material of the cathode is preferably metal, and more preferably aluminum.

The film thickness of the cathode can be appropriately selected taking electric conductivity and durability into consideration and is, for example, from 10 nm to 10 μm, preferably from 20 nm to 1 μm, and more preferably from 50 nm to 500 nm.

It is possible to use, as the method for the production of a cathode, a vacuum deposition method, a sputtering method, a lamination method of thermally bonding a metal thin-film, and the like.

In the above-mentioned embodiment, the description has been made by way of the case where a hole transporting layer 4 was provided on the anode side, in addition to the hole injecting layer 3, while the electron injecting layer 7 was provided on the cathode side without providing the electron transporting layer.

Such structure is, for example, an effective structure when an organic light emitting layer 5 is made of an electron transporting material.

However, the present invention is not limited to the layer structure described in the embodiment, and the organic electroluminescence device of the present invention may include a sodium fluoride layer and an electron injecting layer 7 provided between at least a cathode 8 and an organic light emitting layer 5 in contact with the organic light emitting layer 5, and various modifications mentioned below can be made. The organic electroluminescence device may include a third layer between a second layer and a cathode. The material of the third layer includes metals. Of metals, aluminum is preferred.

The structure of modification according to the present invention includes, for example, the following structures (a) to (g).

(a) Anode/hole injecting layer/light emitting layer/sodium fluoride layer/electron injecting layer/cathode
(b) Anode/hole injecting layer/light emitting layer/sodium fluoride layer/electron transporting layer/electron injecting layer/cathode
(c) Anode/hole injecting layer/hole transporting layer/light emitting layer/sodium fluoride layer/electron transporting layer/electron injecting, layer/cathode
(d) Anode/hole transporting layer/light emitting layer/sodium fluoride layer/electron injecting layer/cathode
(e) Anode/hole transporting layer/light emitting layer/sodium fluoride layer/electron transporting layer/electron injecting layer/cathode
(f) Anode/light emitting layer/sodium fluoride layer/electron injecting layer/cathode
(g) Anode/light emitting layer/sodium fluoride layer/electron transporting layer/electron injecting layer/cathode

In the embodiment according to the present invention, and the layer structures (a) to (g) of modification, a hole blocking layer having a function of blocking holes injected from an anode may be formed on the cathode side, or an electron blocking layer having a function of blocking electrons injected from a cathode may be formed on the anode side.

The electron transporting layer and the hole blocking layer can be formed using the electron transporting organic compound exemplified in the description of the above-mentioned electron injecting layer 7, and the electron blocking layer can be formed using the hole transporting organic compound exemplified in the description of the above-mentioned hole transporting layer.

### EXAMPLES

The present invention will be specifically described below by way of Example and Comparative Examples, but the present invention is not limited to the following Examples.

### Example 1

### 1. Synthesis of Polymeric Compound 1

Under nitrogen atmosphere, 21.218 g of 9,9-dioctyl-(1,3,2-dioxaborolan-2-yl)-fluorene, 5.487 g of 9,9-dioctyl-2,7-dibromofluorene, 16.377 g of N,N-bis(4-bromophenyl)-N′,N′-bis(4-n-butylphenyl)-1,4-phenylenediamine, 2.575 g of N,N-bis(4-bromophenyl)-N-(bicyclo[4.2.0]octa-1,3,5-trien-3-yl)-amine, 5.17 g of methyltrioctylammonium chloride (trade name: Aliquat (registered trademark) 336, manufactured by Aldrich Corporation), and 400 ml of toluene serving as a solvent were charged in a flask. After heating the mixture to 80° C., 56.2 mg of bistriphenylphosophinepalladium dichloride and 109 ml of an aqueous 17.5% by weight sodium carbonate solution were added, followed by stirring under reflux while heating in an oil bath for 6 hours.

Thereafter, 0.49 g of benzeneboronic acid was added, followed by stirring under reflux for 2 hours while heating in an oil bath.

After removing the aqueous layer of the reaction solution by liquid separation, a solution prepared by dissolving 24.3 g of sodium N,N-diethyldithiocarbamate trihydrate in 240 ml of deionized water was added, followed by stirring for 2 hours while heating at 85° C.

After separating the organic layer of the reaction solution from the aqueous layer, the organic layer was washed twice in turn with 520 ml of deionized water, 52 ml of an aqueous 3% by weight acetic acid solution, and 520 ml of deionized water.

Thereafter, the organic layer was added dropwise to methanol to thereby precipitate a polymeric compound, and the polymeric compound was collected by filtration and then dried to obtain a solid.

This solid was dissolved in 1,240 ml of toluene and the solution was passed through a silica gel column and an alumina column, through which toluene was passed in advance, and the obtained solution was added dropwise to 6,200 ml of methanol to thereby precipitate a polymeric compound. The polymeric compound was collected by filtration and then dried to obtain 26.23 g of a polymeric compound 1.

Regarding a polystyrene-equivalent number average molecular weight (Mn) and a polystyrene-equivalent weight average molecular weight (Mw) determined by analysis of gel permeation chromatography of the polymeric compound 1, Mn was 7.8×10⁴ and Mw was 2.6×10⁵. A glass transition temperature of the polymeric compound 1 was 115° C. Due to a charge ratio of starting materials, the polymeric compound 1 might be a polymeric compound including repeating units represented by the following formulas. The numerical value attached to the parenthesis represents a molar fraction of each repeating unit.

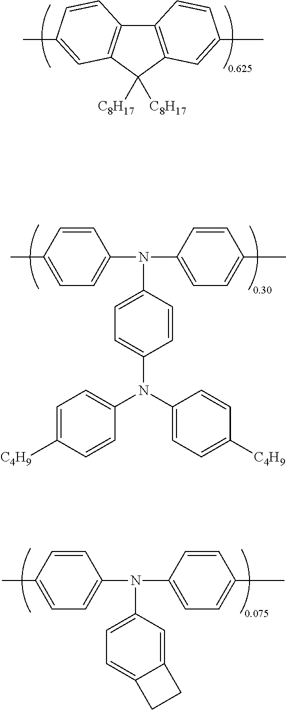

### 2. Synthesis of Polymeric Compound 2

Under inert gas atmosphere, 9.0 g (16.4 mmol) of 2,7-dibromo-9,9-di(octyl)fluorene, 1.3 g (1.8 mmol) of N,N′-bis(4-bromophenyl)-N,N′-bis(4-t-butyl-2,6-dimethylphenyl)1,4-phenylenediamine, 13.4 g (18.0 mmol) of 2,7-bis(4,4,5,5-tetramethyl-1,3,2-dioxaborolan-2-yl)-9,9-di(4-hexylphenyl)fluorene, 43.0 g (58.3 mmol) of tetraethylammonium hydroxide, 8 mg (0.04 mmol) of palladium acetate, 0.05 g (0.1 mmol) of tri(2-methoxyphenyl)phosophine, and 200 mL of toluene were charged in a flask, and then the mixture was heated and stirred at 90° C. for 8 hours. Then, 0.22 g (1.8 mmol) of phenylboronic acid was added and the obtained mixture was stirred for 14 hours. After standing to cool, the aqueous layer of the reaction solution was removed and an aqueous sodium diethyldithiocarbamate solution was added, followed by stirring. Thereafter, the aqueous layer of the reaction solution was removed and the organic layer was washed with water and 3% by weight acetic acid water. After the organic layer was poured into methanol to thereby precipitate a polymer, the polymer collected by filtration was dissolved again in toluene and then the solution was passed through a silica gel column and an alumina column.

The eluted toluene solution containing a polymer was recovered and the recovered toluene solution was poured into methanol to thereby precipitate the polymer. The precipitated polymer was vacuum-dried at 50° C. to obtain 12.5 g of a polymeric compound 2. A polystyrene-equivalent weight average molecular weight determined by analysis of gel permeation chromatography of the polymeric compound 2 was 3.1×10⁵, and a molecular weight distribution index (Mw/Mn) was 2.9.

Due to a charge ratio of starting materials, the polymeric compound 2 is a copolymer including a repeating unit represented by the following formula:

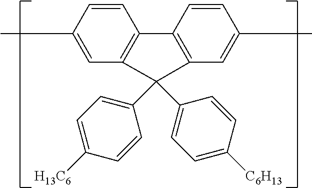

a repeating unit represented by the following formula:

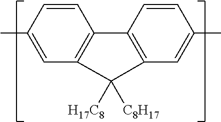

and a repeating unit represented by the following formula:

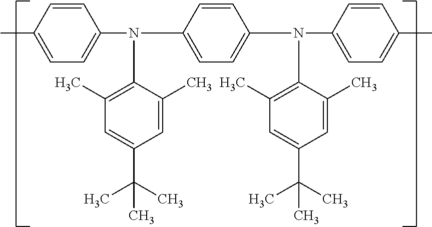

in a molar fraction of 0.50:0.45:0.05.

### 3. Preparation of Polymeric Material Solution

A polymeric compound 1 as a hole transporting material was dissolved in a xylene solvent in the concentration of 0.8% by weight to prepare a hole transporting polymeric material solution 1. Then, a polymeric compound 2 as a light emitting material was dissolved in a xylene solvent in the concentration of 1.3% by weight to prepare a light emitting polymeric material solution 2.

### 4. Production of Organic EL Device

On a glass substrate including an ITO anode film 2 formed thereon, Plexcore OC-RG1200 (manufactured by Aldrich Corporation) was coated by a spin coating method so that the film thickness becomes 35 nm to form a hole injecting layer 3. The glass substrate including the hole injecting layer 3 thus formed thereon was subjected to a heat treatment at 170° C. for 15 minutes thereby to vaporize the solvent.

Then, the hole transporting polymeric material solution 1 prepared in 3. was coated on the hole injecting layer 3 by a spin coating method so that the film thickness becomes 20 nm to form a hole transporting layer 4. The glass substrate including the hole transporting layer 4 thus formed thereon was subjected to a heat treatment at 180° C. for 60 minutes to thereby vaporize the solvent.

Then, the light emitting polymeric material solution 2 prepared in 3. was coated on the hole transporting layer 4 by a spin coating method so that the film thickness becomes 60 nm to form an organic light emitting layer 5. The glass substrate including the organic light emitting layer 5 thus formed thereon was subjected to a heat treatment at 130° C. for 10 minutes to thereby vaporize the solvent.

Then, the glass substrate including the organic light emitting layer 5 thus formed thereon was set in a chamber of a vacuum deposition apparatus, and then a sodium fluoride layer 6, an electron injecting layer 7, and a cathode were sequentially formed by the following procedure.

First, sodium fluoride was deposited on the organic light emitting layer 5 in a film thickness of 4 nm to form a sodium fluoride layer 6.

Then, bathocuproine was prepared as an electron transporting low molecular material, and bathocuproine and barium were deposited by codeposition in a weight ratio of 90:10 in a film thickness of 35 nm to form an electron injecting layer 7.

Subsequently, aluminum was deposited in a film thickness of 100 nm to form a cathode 8.

Then, the glass substrate including the cathode 8 thus formed thereon was sealed using an epoxy resin and a sealing glass plate to produce an organic electroluminuscence device.

### Comparative Example 1

In the same manner as in Example 1, except that the sodium fluoride layer 6 was not formed, an organic electroluminescence device was produced.

### Comparative Example 2

In the same manner as in Example 1, except that lithium fluoride having a film thickness of 0.5 nm was deposited in place of sodium fluoride, an organic electroluminescence device was produced.

### <Evaluation of Device>

Regarding the thus produced organic electroluminescence devices of Examples and Comparative Examples, luminance half-lifetime was evaluated.

The luminance half-lifetime means a continuous operation time required until the luminance is reduced to half of an initial luminance. A luminance half-lifetime test was measured at an initial luminance of 1,000 cd/m², using a constant voltage/constant current power supply.

As a result, the half-lifetime of the organic electroluminescence device of Example 1 was 42 hours, the half-lifetime of the organic electroluminescence device of Comparative Example 1 was 6.3 hours, and the half-lifetime of the organic electroluminescence device of Comparative Example 2 was 19 hours.

### DESCRIPTION OF REFERENCE NUMERALS

1 Substrate
2 Anode
3 Hole injecting layer
4 Hole transporting layer
5 Organic light emitting layer
6 Sodium fluoride layer
7 Electron injecting layer
8 Cathode

1. An organic electroluminescence device comprising:
an anode;
a cathode;
an organic light emitting layer provided between the anode and the cathode;
a first layer made of sodium fluoride provided between the cathode and the organic light emitting layer in contact with the organic light emitting layer; and
a second layer located between the first layer and the cathode, comprising a first material composed of an organic substance, and a second material, the material of the second material being a material capable of donating electrons to the first material.

2. The organic electroluminescence device according to claim 1, wherein a film thickness of the first layer is in a range from 0.1 to 10 nm.

3. The organic electroluminescence device according to claim 1, wherein a weight ratio of the first material to the second material is in a range from 1,000:1 to 5:1 in the second layer.

4. The organic electroluminescence device according to claim 1, wherein the cathode is made of metal.

5. The organic electroluminescence device according to claim 4, wherein the cathode is made of Al.

6. The organic electroluminescence device according to claim 1, further comprising a third layer between the cathode and the second layer, the third layer being made of metal.

7. The organic electroluminescence device according to claim 6, wherein the third layer is made of Al.

8. The organic electroluminescence device according to claim 1, wherein the first material is composed of an electron transporting organic substance.

9. The organic electroluminescence device according to claim 1, wherein the material of the second material is metal.

10. The organic electroluminescence device according to claim 1, wherein the second layer is in contact with the first layer, and the cathode or the third layer is in contact with the second layer.
